(19) United States
(12) Patent Application Publication
(10) Pub. No.: US 2026/0047445 A1
(43) Pub. Date: Feb. 12, 2026

(54) POWER MODULE

(71) Applicant: Delta Electronics, Inc., Taoyuan City (TW)

(72) Inventors: Han-Lin Wu, Taoyuan City (TW); Yu-Hsuan Tsai, Taoyuan City (TW)

(21) Appl. No.: 19/260,140

(22) Filed: Jul. 3, 2025

(30) Foreign Application Priority Data
Aug. 12, 2024 (CN) 202411099092.3

(51) Int. Cl. H01L 23/492; H01L 23/495

(52) U.S. Cl. CPC H01L 23/492; H01L 23/49534; H01L 23/49555

(57) ABSTRACT

A power module is provided. The power module is disposed on a main board. The power component includes a first surface, a second surface, a source terminal, a gate terminal and a drain terminal. The source terminal and the gate terminal are disposed on the first surface. The drain terminal is disposed on the second surface. The first solder layer is attached to the first surface and connected with the source terminal and the gate terminal. The first solder layer is disposed on a metal surface of the main board. The second solder layer is attached to the second surface and connected with the drain terminal. The drain terminal is away from the main board than the source terminal and the gate terminal. The conductive component is connected with the first solder layer and the second solder layer.

### CROSS-REFERENCE TO RELATED APPLICATION

This application claims the priority to China Patent Application No. 202411099092.3 filed on Aug. 12, 2024, the entirety of which is hereby incorporated by reference.

### FIELD OF THE INVENTION

The present disclosure relates to a power module, and more particularly to a power module for reducing the volume.

### BACKGROUND OF THE INVENTION

The conventional power module includes a source terminal, a gate terminal and a drain terminal. The source terminal and the gate terminal are disposed on a first surface of the power module. The drain terminal is disposed on a second surface apposite to the first surface of the power module. The second surface (i.e., the surface having the drain terminal) of the conventional power module is disposed on a main board. The first surface (i.e., the surface having the source terminal and the gate terminal) of the conventional power module is away from the main board. Consequently, the source terminal disposed on the first surface of the conventional power module is connected with the main board through an additional wire bonding for receiving current and signal.

The conventional power module needs the additional wire bonding to connect the source terminal with the main board. However, the conventional power module and the main board require more space to accommodate the additional wire bonding. Consequently, the volume of the conventional power module is increased, the conduction path of current and signal is increased, the parasitic inductance is enhanced and the signal delay is enhanced.

Therefore, there is a need of providing a power module to obviate the drawbacks encountered from the prior arts.

### SUMMARY OF THE INVENTION

The present disclosure provides a power module. The source terminal of the power module is disposed on the first surface of the power component and disposed on the metal surface of the main board through the first lead frame. Namely, the source terminal of the power module of the present disclosure is directly attached to the metal surface of the main board through the first lead frame. The source terminal of the power module is electrically connected with the metal surface of the main board to receive the current provided by the main board so as to connect with the main board without additional wire bonding for receiving the current and the signal. Consequently, the power module of the present disclosure has the advantages of reducing volume, reducing conductive paths for current and signal, reducing parasitic inductance and minimizing signal delay.

In accordance with an aspect of the present disclosure, a power module is provided. The power module is disposed on a main board. The main board includes a metal surface. The power module includes a power component, a first solder layer, a second solder layer and a conductive component. The power component includes a first surface, a second surface, a source terminal, a gate terminal and a drain terminal. The first surface and the second surface are opposite to each other. The source terminal and the gate terminal are disposed on the first surface. The drain terminal is disposed on the second surface. The first solder layer is attached to the first surface of the power component and connected with the source terminal and the gate terminal. The first solder layer is disposed on the metal surface of the main board. The second solder layer is attached to the second surface of the power component and connected with the drain terminal. The drain terminal is away from the main board than the source terminal and the gate terminal. The conductive component is connected with the first solder layer and the second solder layer.

In accordance with another aspect of the present disclosure, a power module is provided. The power module is disposed on a main board and connected with an electronic device. The main board includes a metal surface. The power module includes a first lead frame, a power component and a second lead frame. The first lead frame includes a first carrier and a first conductive pin. The first carrier includes a first surface and a second surface. The first surface and the second surface of the first carrier are opposite to each other. The first surface of the first carrier is disposed on the metal surface of the main board. The first conductive pin is electrically connected with the electronic device. The power component includes a first surface, a second surface, a source terminal, a gate terminal and a drain terminal. The first surface and the second surface of the power component are opposite to each other. The source terminal and the gate terminal are disposed on the first surface of the power component. The drain terminal of the power component is disposed on the second surface of the first carrier. The first surface of the power component is disposed on the second surface of the first carrier. The second lead frame includes a second carrier and a second conductive pin. The second carrier is disposed on the second surface of the power component. The second conductive pin is electrically connected with the electronic device.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1 is a schematic view illustrating a power module according to a first embodiment of the present disclosure;

FIG. 2 is a schematic view illustrating the power module of FIG. 1 taken along another viewpoint;

FIG. 3 is a schematic exploded view illustrating the power module of FIG. 1;

FIG. 4 is a side view illustrating the power module of FIG. 1;

FIG. 5 is a schematic view illustrating a power module according to a second embodiment of the present disclosure;

FIG. 6 is a schematic view illustrating the power module of FIG. 5 taken along another viewpoint;

FIG. 7 is a schematic exploded view illustrating the power module of FIG. 5;

FIG. 8 is a side view illustrating the power module of FIG. 5;

FIG. 9 is a schematic view illustrating a power module according to a third embodiment of the present disclosure;

FIG. 10 is a schematic view illustrating the power module of FIG. 9 taken along another viewpoint;

FIG. 11 is a schematic exploded view illustrating the power module of FIG. 9; and

FIG. 12 is a side view illustrating the power module of FIG. 9.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

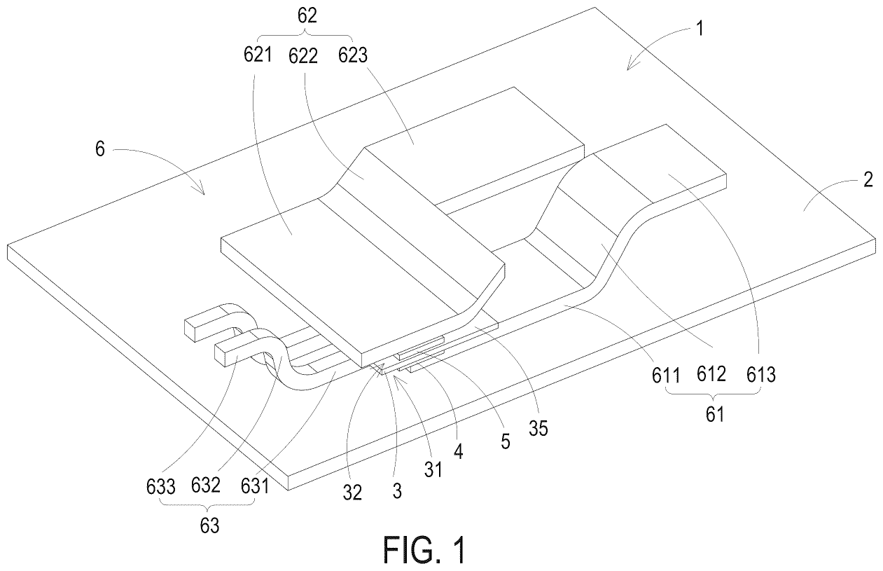

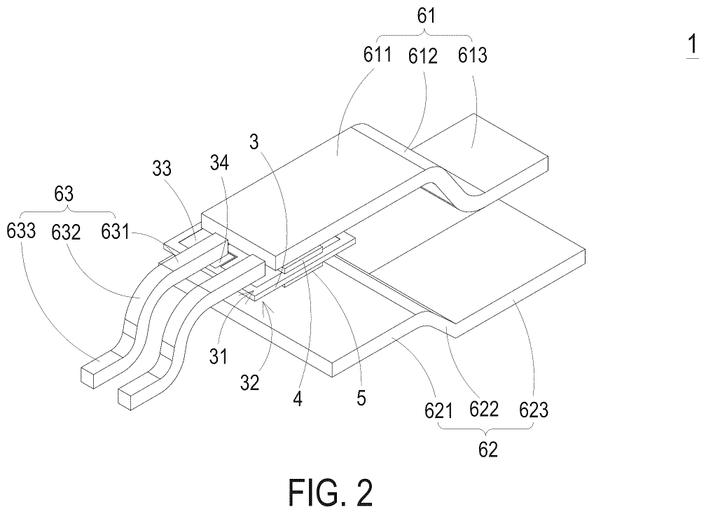

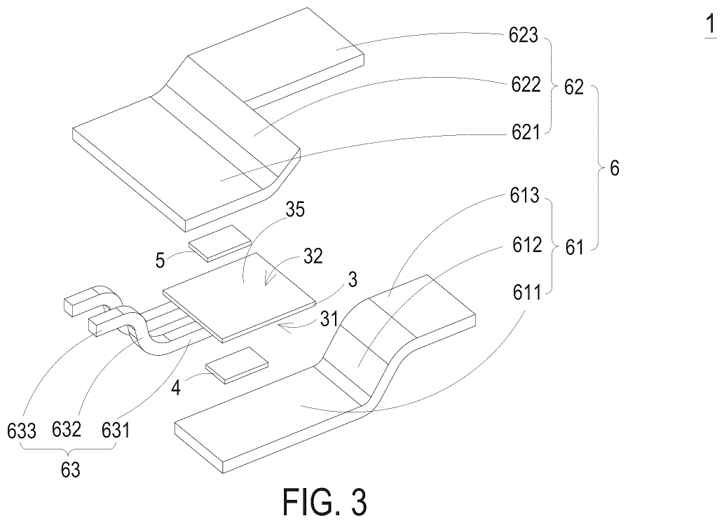

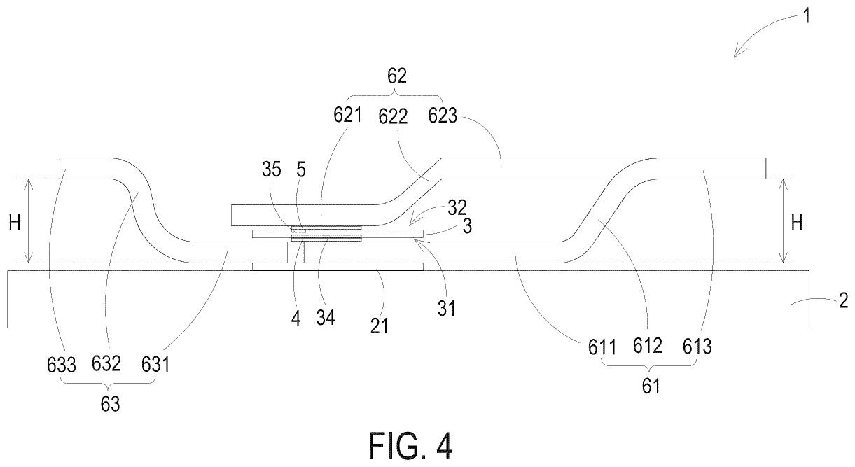

FIG. 1 is a schematic view illustrating a power module according to a first embodiment of the present disclosure. FIG. 2 is a schematic view illustrating the power module of FIG. 1 taken along another viewpoint. FIG. 3 is a schematic exploded view illustrating the power module of FIG. 1. FIG. 4 is a side view illustrating the power module of FIG. 1. As shown in FIGS. 1 and 4, the power module 1 of this embodiment is disposed on a main board 2. The main board 2 includes a metal surface 21. For simplifying the figure, the main board is not shown in FIGS. 2 and 3.

As shown in FIGS. 1 and 4, the power module 1 includes a power component 3, a first solder layer 4, a second solder layer 5 and a conductive component 6. The power component 3 includes a first surface 31, a second surface 32, a source terminal 33, a gate terminal 34 and a drain terminal 35. The first surface 31 and the second surface 32 of the power component 3 are opposite to each other. The source terminal 33 and the gate terminal 34 are disposed on the first surface 31 of the power component 3. The drain terminal 35 is disposed on the second surface 32 of the power component 3. The drain terminal 35 is away from the main board 2 than the source terminal 33 and the gate terminal 34. The source terminal 33 and the gate terminal 34 are adjacent to the main board 2 than the drain terminal 35. The first solder layer 4 is conductive material, attached to the first surface 31 of the power component 3, and connected with the source terminal 33 and the gate terminal 34. The first solder layer 4 is disposed on the metal surface 21 of the main board 2. Namely, the first solder layer 4 is disposed between the first surface 31 of the power component 3 and the metal surface 21 of the main board 2. The second solder layer 5 is conductive material, attached to the second surface 32 of the power component 3, and connected with the drain terminal 35. The second solder layer 5 is away from the main board 2 than the first solder layer 4.

The conductive component 6 includes a first lead frame 61, a second lead frame 62 a third lead frame 63. The first lead frame 61 is disposed on a surface of the first solder layer 4 away from the power component 3, and disposed between the first solder layer 4 and the metal surface 21 of the main board 2, as shown in FIG. 4. The first lead frame 61 includes a first carrier 611, a first bending portion 612 and a first conductive pin 613. The first carrier 611 is attached between the first solder layer 4 and the metal surface 21 of the main board 2. Consequently, the source terminal 33 of the power component 3 receives the current provided from the metal surface 21 of the main board 2 through the first carrier 611 of the first lead frame 61 and the first solder layer 4. The first bending portion 612 is bended from the first carrier 611 and extended away from the main board 2. The first conductive pin 613 is extended from the first bending portion 612 away from the first carrier 611. A distance H is formed between the extension direction of the first conductive pin 613 and the extension direction of the first carrier 611 so as to form the space between the first conductive pin 613 and the main board 2 for decreasing the manufacturing difficulty.

The second lead frame 62 is disposed on a surface of the second solder layer 5 away from the power component 3, as shown in FIG. 4. The second lead frame 62 includes a second carrier 621, a second bending portion 622 and a second conductive pin 623. The second carrier 621 is attached to a surface of the second solder layer 5 away from the power component 3. Namely, the second solder layer 5 is disposed between the second carrier 621 and the second surface 32 of the power component 3. The second bending portion 622 is bended from the second carrier 621 and extended away from the main board 2. The second conductive pin 623 is extended from the second bending portion 622 away from the second carrier 621, and electrically connected with an electronic device (not shown in figure). Consequently, the current of the drain terminal 35 flows to the electronic device through the second solder layer 5 and the second conductive pin 623 of the second lead frame 62. A distance H is formed between the extension direction of the second conductive pin 623 and the extension direction of the second carrier 621 so as to form the space between the second conductive pin 623 and the main board 2 for decreasing the manufacturing difficulty. In this embodiment, as shown in FIG. 1, the second conductive pin 623 of the second lead frame 62 and the first conductive pin 613 of the first lead frame 61 are staggered with each other on the main board 2.

The third lead frame 63 is disposed on the first surface 31 of the power component 3 and connected with the gate terminal 34 of the power component 3, as shown in FIG. 2. The third lead frame 63 includes a third carrier 631, a third bending portion 632 and a third conductive pin 633. The third carrier 631 is attached to the gate terminal 34 of the power component 3. The third bending portion 632 is extended and bended from the third carrier 631. The third conductive pin 633 is extended from the third bending portion 632 away from the third carrier 631, and electrically connected with the electronic device (not shown in figure). Consequently, the voltage of the gate terminal 34 is controlled by the other power sources (not shown in figure) through the third conductive pin 633 of the third lead frame 63. A distance H is formed between the extension direction of the third conductive pin 633 and the extension direction of the third carrier 631. In this embodiment, as shown in FIG. 4, the third conductive pin 633 of the third lead frame 63, the second conductive pin 623 of the second lead frame 62 and the first conductive pin 613 of the first lead frame 61 are coplanar with one another.

From above, the source terminal 33 of the power module 1 is disposed on the first surface 31 of the power component 3 and disposed on the metal surface 21 of the main board 2 through the first lead frame 61. Namely, the source terminal 33 of the power module 1 of the present disclosure is directly attached to the metal surface 21 of the main board 2 through the first lead frame 61. The source terminal 33 of the power module 1 is electrically connected with the metal surface 21 of the main board 2 to receive the current provided by the main board 2 so as to connect with the main board 2 without additional wire bonding for receiving the current and the signal. Consequently, the power module 1 of the present disclosure has the advantages of reducing volume, reducing conductive paths for current and signal, reducing parasitic inductance and minimizing signal delay.

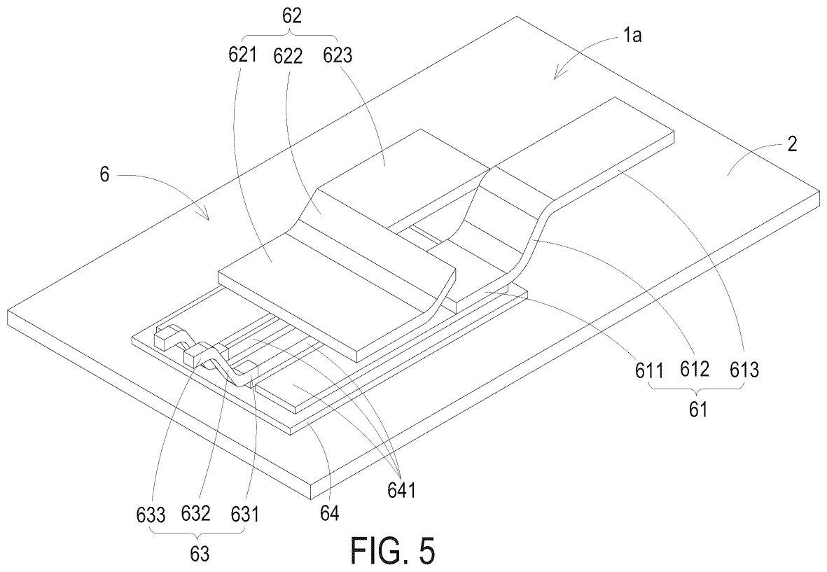

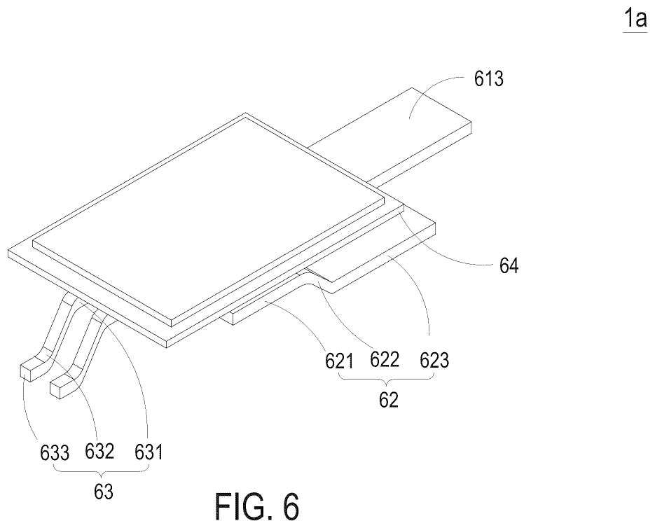

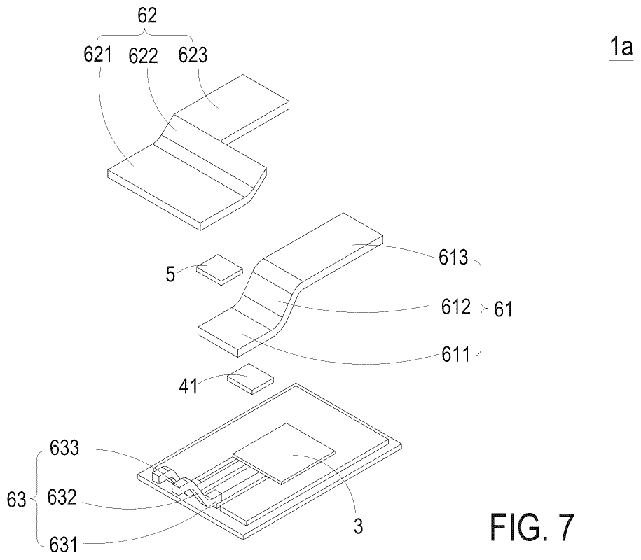

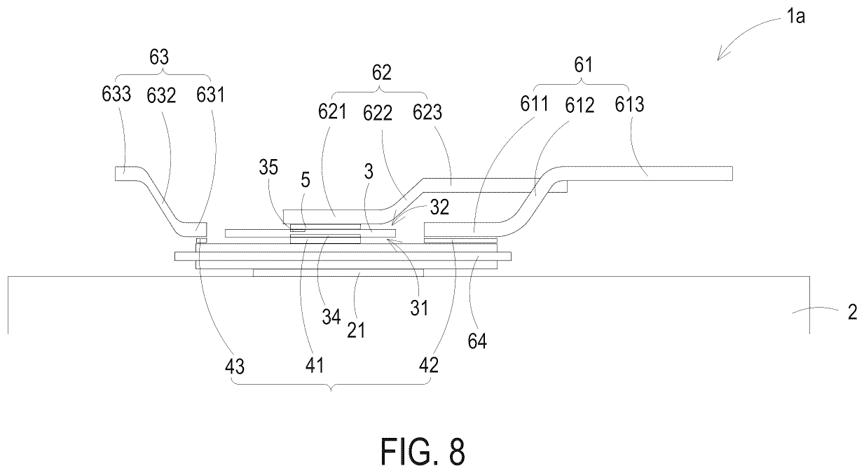

In some embodiment, the arrangement of the conductive component of the power module can be adjusted according to the practical requirement. FIG. 5 is a schematic view illustrating a power module according to a second embodiment of the present disclosure. FIG. 6 is a schematic view illustrating the power module of FIG. 5 taken along another viewpoint. FIG. 7 is a schematic exploded view illustrating the power module of FIG. 5. FIG. 8 is a side view illustrating the power module of FIG. 5. As shown in FIGS. 5 and 8, the power module 1a of this embodiment is disposed on the main board 2. For simplifying the figure, the main board is not shown in FIGS. 6 and 7. In the first embodiment of FIGS. 1 to 4, the first carrier 611 of the first carrier 61 of the power module 1 is directly attached to the first solder layer 4, and the third carrier 631 of the third lead frame 63 is directly attached to the gate terminal 34 of the power component 3. As shown in FIGS. 5 to 8, compared with the power module 1 of the first embodiment, the conductive component 6 of the power module 1a of this embodiment includes a substrate for connecting. In this embodiment, the conductive component 6 of the power module 1a includes a first substrate 64. The first substrate 64 is disposed on a surface of the first solder layer 4 away from the power component 3 and disposed between the first solder layer 4 and the metal surface 21 of the main board 2. The first substrate 64 includes a plurality of conductive terminals 641. Consequently, the source terminal 33 disposed on the first surface 31 of the power component 3 receives the current provided by the main board 2 through the first solder layer 4 and the plurality of conductive terminals 641 of the first substrate 64.

As shown in FIG. 8, the first solder layer 4 of the power module 1a of this embodiment includes a first solder part 41, a second solder part 42 and a third solder part 43. The first solder part 41, the second solder part 42 and the third solder part 43 are disposed on the first substrate 64 separated from one another. The first solder part 61 is disposed between the first surface 31 of the power component 3 and the corresponding conductive terminal 641 of the first substrate 64. The second solder part 42 is attached to the first carrier 611 of the first lead frame 61. The second solder part 42 is disposed between the first carrier 611 of the first lead frame 61 and the corresponding conductive terminal 641 of the first substrate 64. The third solder part 43 is attached to the third carrier 631 of the third lead frame 63. The solder part 43 is disposed between the third carrier 631 of the third lead frame 63 and the corresponding conductive terminal 641 of the first substrate 64. The second lead frame 62 of the power module 1a of this embodiment is similar to the second lead frame 62 of the first embodiment, and is not redundantly described hereinafter.

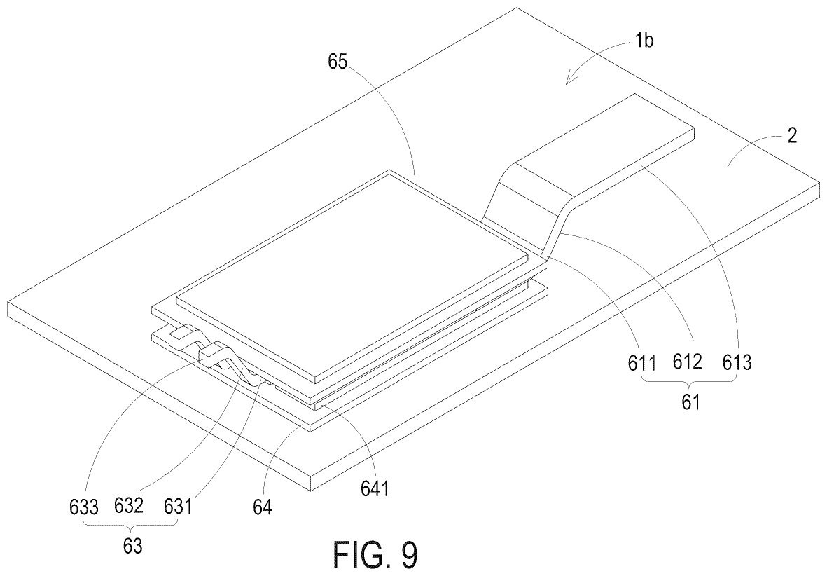

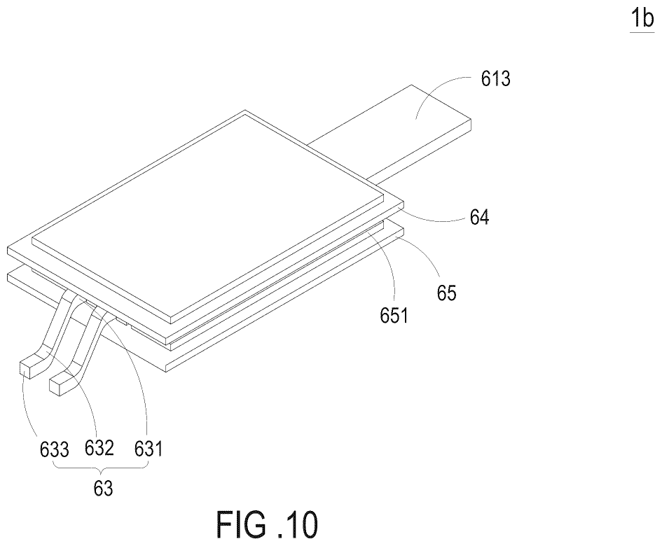

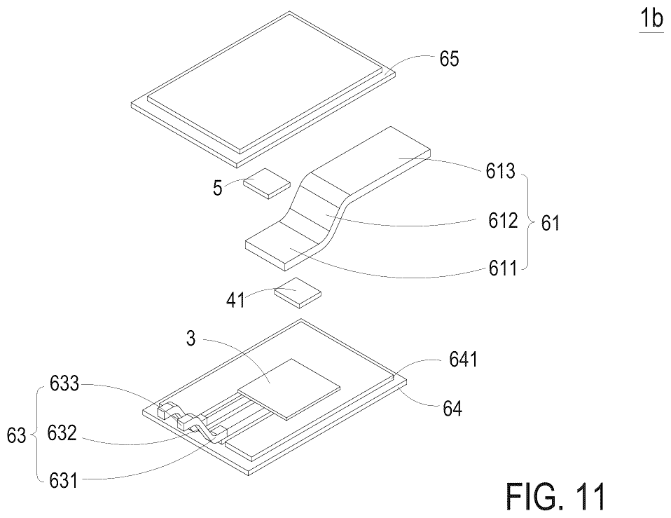

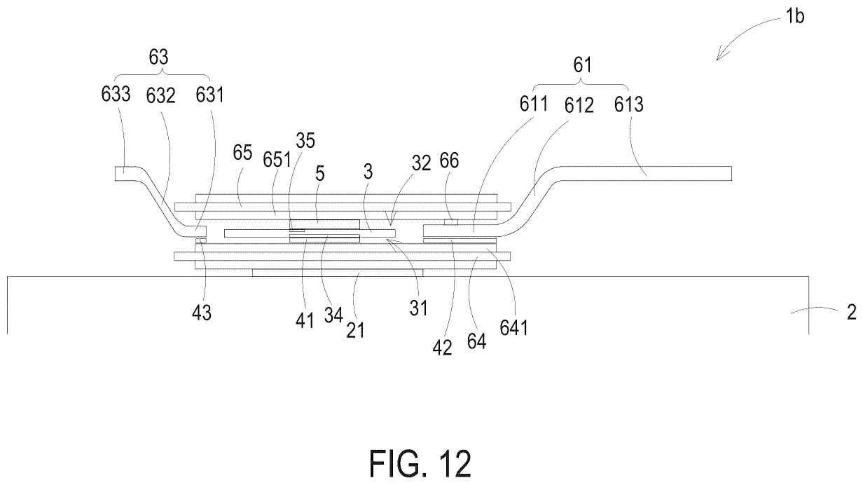

FIG. 9 is a schematic view illustrating a power module according to a third embodiment of the present disclosure. FIG. 10 is a schematic view illustrating the power module of FIG. 9 taken along another viewpoint. FIG. 11 is a schematic exploded view illustrating the power module of FIG. 9. FIG. 12 is a side view illustrating the power module of FIG. 9. As shown in FIGS. 9 and 12, the power module 1b of this embodiment is disposed on a main board 2. For simplifying the figure, the main board is not shown in FIGS. 10 and 11. Compared with the power module 1a of the second embodiment, the power module 1b of this embodiment does not include a second lead frame but a second substrate 65. In this embodiment, the second substrate 65 of the conductive component 6 of the power module 1b is connected with a surface of the second solder layer 5 away from the power component 3. The second substrate 65 and the first substrate 64 are disposed on two opposite sides of the power component 3, respectively. The second substrate 65 includes a plurality of conductive terminals 651. In this embodiment, the conductive component 6 further includes a conductive pillar 66 disposed between the corresponding conductive terminal 651 of the second substrate 65 and the first carrier 611 of the first lead frame 61. Consequently, the current provided by the drain terminal 35 disposed on the second surface 32 of the power component 3 flows to the first lead frame 61 through the second solder layer 5 and the conductive terminal 651 of the second substrate 65.

As mentioned above, the present disclosure discloses a power module. The source terminal of the power module is disposed on the first surface of the power component and disposed on the metal surface of the main board through the first lead frame. Namely, the source terminal of the power module of the present disclosure is directly attached to the metal surface of the main board through the first lead frame. The source terminal of the power module is electrically connected with the metal surface of the main board to receive the current provided by the main board so as to connect with the main board without additional wire bonding for receiving the current and the signal. Consequently, the power module of the present disclosure has the advantages of reducing volume, reducing conductive paths for current and signal, reducing parasitic inductance and minimizing signal delay.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power module disposed on a main board, wherein the main board comprises a metal surface, and the power module comprises:
a power component comprising a first surface, a second surface, a source terminal, a gate terminal and a drain terminal, wherein the first surface and the second surface are opposite to each other, the source terminal and the gate terminal are disposed on the first surface, and the drain terminal is disposed on the second surface;
a first solder layer attached to the first surface of the power component and connected with the source terminal and the gate terminal, wherein the first solder layer is disposed on the metal surface of the main board;
a second solder layer attached to the second surface of the power component and connected with the drain terminal, wherein the drain terminal is away from the main board than the source terminal and the gate terminal; and
a conductive component connected with the first solder layer and the second solder layer.

2. The power module according to claim 1, wherein the conductive component comprises a first lead frame disposed on a surface of the first solder layer away from the power component and disposed between the first solder layer and the metal surface of the main board, wherein the first lead frame comprises a first carrier, a first bending portion and a first conductive pin, the first carrier is attached between the first solder layer and the metal surface of the main board, wherein the first bending portion is bended from the first carrier, the first conductive pin is extended from the first bending portion away from the first carrier, and a distance is formed between an extension direction of the first conductive pin and an extension direction of the first carrier.

3. The power module according to claim 1, wherein the conductive component comprises a second lead frame disposed on a surface of the second solder layer away from the power component, the second lead frame comprises a second carrier, a second bending portion and a second conductive pin, wherein the second carrier is attached to a surface of the second solder layer, the second bending portion is bended from the second carrier, the second conductive pin is extended from the second bending portion away from the second carrier, and a distance is formed between an extension direction of the second conductive pin and an extension direction of the second carrier.

4. The power module according to claim 1, wherein the conductive component comprises a third lead frame disposed on the first surface of the power component, and the third lead frame comprises a third carrier, a third bending portion and a third conductive pin, wherein the third carrier is attached to the gate terminal, the third bending portion is extended and bended from the third carrier, the third conductive pin is extended from the third bending portion away from the third carrier, wherein a distance is formed between an extension direction of the third conductive pin and an extension direction of the third carrier.

5. The power module according to claim 1, wherein the conductive component comprises a first substrate disposed on a surface of the first solder layer away from the power component and disposed between the first solder layer and the metal surface of the main board, wherein the first substrate comprises a plurality of conductive terminals, wherein the first solder layer comprises a first solder part, a second solder part and a third solder part, the first solder part, the second solder part and the third solder part are disposed on the first substrate separated from one another, and the first solder part is disposed between the power component and corresponding one of the plurality of conductive terminals of the first substrate.

6. The power module according to claim 5, wherein the conductive component comprises a first lead frame disposed on the second solder part of the first solder layer, wherein the second solder part is disposed between the first lead frame and corresponding one of the plurality of conductive terminals of the first substrate, wherein the first lead frame comprises a first carrier, a first bending portion and a first conductive pin, the first carrier is attached to the second solder part of the first solder layer, the first bending portion is bended from the first carrier, the first conductive pin is extended from the first bending portion away from the first carrier, and a distance is formed between an extension direction of the first conductive pin and an extension direction of the first carrier.

7. The power module according to claim 6, wherein the conductive component comprises a second substrate connected with a surface of second solder layer away from the power component, and the second substrate and the first substrate are disposed on two opposite sides of the power component, respectively.

8. The power module according to claim 7, wherein the conductive component comprises a conductive pillar disposed between the second substrate and the first carrier of the first lead frame.

9. The power module according to claim 5, wherein the conductive component comprises a second lead frame disposed on a surface of the second solder layer away from the power component, wherein the second lead frame comprises a second carrier, a second bending portion and a second conductive pin, the second carrier is attached to the second solder layer, the second bending portion is bended from the second carrier, the second conductive pin is extended from the second bending portion away from the second carrier, and a distance is formed between an extension direction of the second conductive pin and an extension direction of the second carrier.

10. The power module according to claim 5, wherein the conductive component comprises a third lead frame disposed on the first surface of the power component, the third lead frame comprises a third carrier, a third bending portion and a third conductive pin, the third carrier is attached to the third solder part of the first solder layer, the third bending portion is extended and bended from the third carrier, the third conductive pin is extended from the third bending portion away from the third carrier, and a distance is formed between an extension direction of the third conductive pin and an extension direction of the third carrier.

11. A power module disposed on a main board and connected with an electronic device, the main board comprising a metal surface, and the power module comprising:
a first lead frame comprising a first carrier and a first conductive pin, wherein the first carrier comprises a first surface and a second surface, the first surface and the second surface of the first carrier are opposite to each other, the first surface of the first carrier is disposed on the metal surface of the main board, and the first conductive pin is electrically connected with the electronic device;
a power component comprising a first surface, a second surface, a source terminal, a gate terminal and a drain terminal, wherein the first surface and the second surface of the power component are opposite to each other, the source terminal and the gate terminal are disposed on the first surface of the power component, and the drain terminal of the power component is disposed on the second surface of the first carrier, wherein the first surface of the power component is disposed on the second surface of the first carrier; and
a second lead frame comprising a second carrier and a second conductive pin, wherein the second carrier is disposed on the second surface of the power component, and the second conductive pin is electrically connected with the electronic device.

12. The power module according to claim 11, wherein the power module a first solder layer and a second solder layer, the first solder layer is attached to a surface of the first solder layer away from the power component and connected with the source terminal and the gate terminal, the first solder layer is disposed on the metal surface of the main board, the second solder layer is attached to the second surface of the power component and connected with the drain terminal, and the drain terminal is away from the main board than the source terminal and the gate terminal.

13. The power module according to claim 12, wherein the first lead frame is disposed on a surface of the first solder layer away from the power component and disposed between the first solder layer and the metal surface of the main board, wherein the first lead frame comprises a first bending portion, wherein the first carrier is attached between the first solder layer and the metal surface of the main board, the first bending portion is bended from the first carrier, the first conductive pin is extended from the first bending portion away from the first carrier, and a distance is formed between an extension direction of the first conductive pin and an extension direction of the first carrier.

14. The power module according to claim 12, wherein the second lead frame is disposed on a surface of the second solder layer away from the power component, wherein the second lead frame comprises a second bending portion, wherein the second carrier is attached to a surface of the second solder layer, the second bending portion is bended from the second carrier, the second conductive pin is extended from the second bending portion away from the second carrier, and a distance is formed between an extension direction of the second conductive pin and an extension direction of the second carrier.

15. The power module according to claim 12, wherein the conductive component comprises a third lead frame disposed on the first surface of the power component, wherein the third lead frame comprises a third carrier, a third bending portion and a third conductive pin, the third carrier is attached to the gate terminal, the third bending portion is extended and bended from the third carrier, the third conductive pin is extended from the third bending portion away from the third carrier, and a distance is formed between an extension direction of the third conductive pin and an extension direction of the third carrier.

16. The power module according to claim 12, wherein the power module comprises a first substrate disposed on a surface of the first solder layer away from the power component and disposed between the first solder layer and the metal surface of the main board, wherein the first substrate comprises a plurality of conductive terminals, the first solder layer comprises a first solder part, a second solder part and a third solder part, the first solder part, the second solder part and the third solder part are disposed on the first substrate separated from one another, and the first solder part is disposed between the power component and corresponding one of the plurality of conductive terminals of the first substrate.

17. The power module according to claim 16, wherein the first lead frame disposed on the second solder part of the first solder layer, wherein the second solder part is disposed between the first lead frame and corresponding one of the plurality of conductive terminals of the first substrate, the first lead frame comprises a first bending portion, wherein the first carrier is attached to the second solder part of the first solder layer, the first bending portion is bended from the first carrier, the first conductive pin is extended from the first bending portion away from the first carrier, and a distance is formed between an extension direction of the first conductive pin and an extension direction of the first carrier.

18. The power module according to claim 17, wherein the power module comprises a second substrate connected with a surface of second solder layer away from the power component, and the second substrate and the first substrate are disposed on two opposite sides of the power component, respectively, wherein the power module comprises a conductive pillar disposed between the second substrate and the first carrier of the first lead frame.

19. The power module according to claim 16, wherein the second lead frame disposed on a surface of the second solder layer away from the power component, the second lead frame comprises a second bending portion, the second carrier is attached to the second solder layer, the second bending portion is bended from the second carrier, the second conductive pin is extended from the second bending portion away from the second carrier, and a distance is formed between an extension direction of the second conductive pin and an extension direction of the second carrier.

20. The power module according to claim 16, wherein the power module comprises a third lead frame disposed on the first surface of the power component, the third lead frame comprises a third carrier, a third bending portion and a third conductive pin, the third carrier is attached to the third solder part of the first solder layer, the third bending portion is extended and bended from the third carrier, the third conductive pin is extended from the third bending portion away from the third carrier, and a distance is formed between an extension direction of the third conductive pin and an extension direction of the third carrier.
